(19) United States
(12) Patent Application Publication
(10) Pub. No.: US 2021/0157253 A1
(43) Pub. Date: May 27, 2021

(54) SEMICONDUCTOR DEVICE, OPTICAL PRINT HEAD AND IMAGE FORMING APPARATUS THEREWITH

(71) Applicant: Oki Data Corporation, Tokyo (JP)

(72) Inventors: Genichirou MATSUO, Tokyo (JP); Hironori FURUTA, Tokyo (JP); Shinya JYUMONJI, Tokyo (JP); Hiroto KAWADA, Tokyo (JP); Kenichi TANIGAWA, Tokyo (JP)

(21) Appl. No.: 16/953,506

(22) Filed: Nov. 20, 2020

(30) Foreign Application Priority Data
Nov. 22, 2019 (JP) 2019-211091

(51) Int. Cl. G03G 15/04; H01L 25/075; H01L 33/56

(52) U.S. Cl. CPC G03G 15/04054; H01L 33/0008; H01L 33/56; H01L 25/0753

(57) ABSTRACT

A semiconductor device includes a base material and light emitting elements (or LEE) aligned in a first direction on the base material. Among the LEEs, a first LEE is provided with a first semiconductor multilayer structure and a first organic insulating film. Among the LEEs, a second LEE is provided with a second semiconductor multilayer structure and a second organic insulating film. A first multilayer structure width is smaller than a second multilayer structure width that is the first direction width of the second semiconductor multilayer structure, a first multilayer structure thickness is narrower than a second multilayer structure thickness, and a first film thickness is greater than a second film thickness wherein the first film thickness is a thickness of a portion of the first organic insulating film and a second film thickness is a thickness of a portion of the second organic insulating film.

### TECHNICAL FIELD

This invention relates to a semiconductor device having multiple light emitting elements, an optical print head having multiple semiconductor devices, and an image forming apparatus having the optical print head.

### BACKGROUND

Conventionally used as an exposure device in an electrophotographic image forming apparatus is an optical print head having multiple light emitting element array chips as multiple semiconductor devices. Each of the light emitting element array chips has multiple light emitting thyristors arranged on a base material in the long direction of the base material (for example, see Patent Doc. 1).

### RELATED ART

### Patent Document(s)

[Patent Doc. 1] JP Laid-Open Patent Application Publication 2010-239084 (for example, FIG. 9)

### Object(S) to be Solved

In general, on the same light emitting chip array chip, among multiple light emitting thyristors arranged on a base material, the amount of light emitted (that is, emitted light intensity) from each of the light emitting thyristors closest to the long-direction ends of the base material becomes greater than the amount of light emitted from each of the light emitting thyristors other than the light emitting thyristors closest to the ends. Considered as a countermeasure is that the amount of light is suppressed by reducing a drive current supplied to the light emitting thyristors closest to the ends. However, if a light emitting element array chip is continuously driven, the amount of light emitted from each light emitting thyristor varies along with its drive time, and the variation amount depends on the drive current value. Therefore, if the drive current values are set different among the light emitting thyristors, there occurs a scatter in the amounts of light emitted from the multiple light emitting thyristors.

This invention has been made for solving the above-mentioned problem, and its objective is to offer a semiconductor device that can uniformize the amounts of emitted light and light emission shapes of multiple light emitting elements, an optical print head having this semiconductor device, and an image forming apparatus having this optical print head.

### SUMMARY

A semiconductor device, disclosed in the application, include a base material, and a plurality of light emitting elements aligned in a first direction on the base material. Wherein among the light emitting elements, a first light emitting element that is one light emitting element, which is positioned closest to a base material end part that is an end part of the base material in the first direction, is provided with a first semiconductor multilayer structure and a first organic insulating film covering at least side faces of the first semiconductor multilayer structure in the first direction, among the light emitting elements, a second light emitting element that is a different light emitting element from the first light emitting element is provided with a second semiconductor multilayer structure and a second organic insulating film covering at least side faces of the second semiconductor multilayer structure in the first direction, a first multilayer structure width that is the first direction width of the first semiconductor multilayer structure is smaller than a second multilayer structure width that is the first direction width of the second semiconductor multilayer structure, a first multilayer structure thickness is narrower than a second multilayer structure thickness wherein the first multilayer structure thickness is a thickness of the first semiconductor multilayer structure determined in the first direction, and the second multilayer structure thickness is a thickness of the second semiconductor multilayer structure determined in the first direction, and a first film thickness is greater than a second film thickness wherein the first film thickness is a thickness of a portion of the first organic insulating film that covers one of the side faces of the first semiconductor multilayer structure, which is closer to the base material end part than the other of the side faces, and the second film thickness is a thickness of a portion of the second organic insulating film that covers one of the side faces of the second semiconductor multilayer structure, which is closer to the base material end part that the other of the side faces.

According to this invention, the amounts of emitted light and light emission shapes of multiple light emitting elements can be uniformized.

### BRIEF DESCRIPTION OF THE DRAWINGS

FIG. 1 is a plan view showing schematically the configuration of a semiconductor device of the first embodiment of this invention.

FIG. 2 is a diagram showing schematically a cross section along a line S2-S2 of the semiconductor device in FIG. 1.

FIG. 3A is a diagram showing schematically a cross section along a line S3a-S3a of the semiconductor device in FIG. 1, and FIG. 3B is a diagram showing schematically a cross section along a line S3b-S3b of the semiconductor device in FIG. 1.

FIGS. 4A and 4B are cross-sectional views showing schematically the manufacturing process of a semiconductor thin film that is the basis of semiconductor multilayer structures of the semiconductor device of the first embodiment.

FIG. 5 is a cross-sectional view showing the sizes of individual parts of the semiconductor device of the first embodiment.

FIG. 6 is a diagram showing light beams emitted from light emitting elements of the semiconductor device of the first embodiment.

FIG. 7 is a cross-sectional view showing schematically the configuration of a semiconductor device of Comparative Example 1.

FIG. 8 is a diagram showing light beams emitted from light emitting elements of the semiconductor device of Comparative Example 1.

FIG. 9 is a cross-sectional view showing schematically the configuration of a semiconductor device of Comparative Example 2.

FIG. 10 is a diagram showing light beams emitted from light emitting elements of the semiconductor device of Comparative Example 2.

FIG. 11 is a perspective view showing the structure of the main part of an optical print head of the second embodiment of this invention.

FIG. 12 is a cross-sectional view showing the structure of the optical print head of the second embodiment.

FIG. 13 is a cross-sectional view showing schematically the configuration of an image forming apparatus of the third embodiment of this invention.

### DETAILED DESCRIPTION OF THE PREFERRED EMBODIMENT(S)

Below, semiconductor devices, optical print heads, and image forming apparatuses of embodiments of this invention are explained referring to drawings. The semiconductor device is, for example, is a light emitting element array chip having multiple light emitting elements. The optical print head is, for example, an exposure device having multiple light emitting array chips. The image forming apparatus is a printer, a copier, a multifunction peripheral, or the like that forms an image on a recording medium using an electrophotographic system. The following embodiments are merely examples, and various modifications are possible within the scope of this invention.

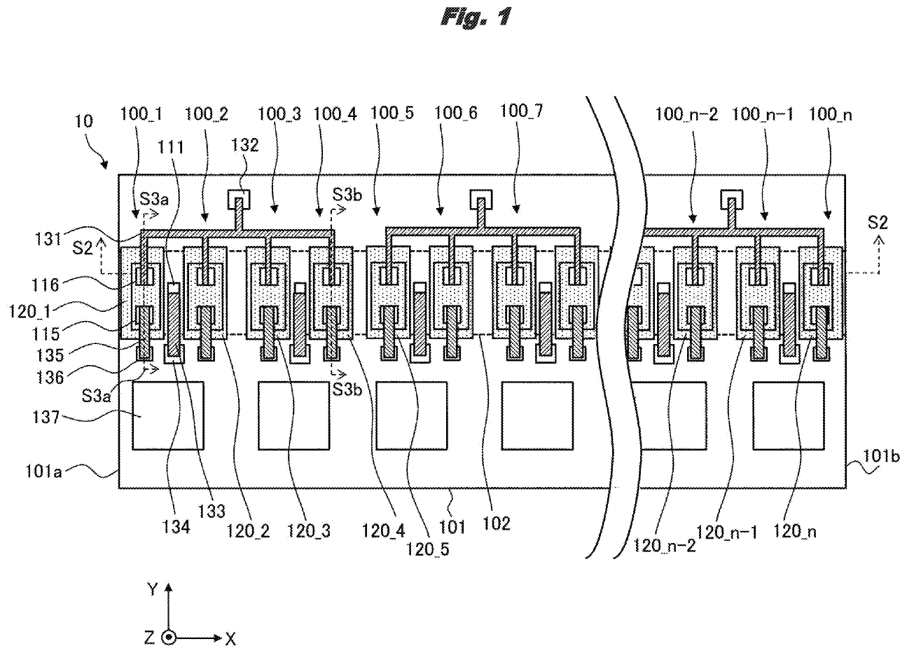

Also, shown in FIGS. 1˜3B and 5˜10 are coordinate axes of the XYZ orthogonal coordinate system. X axis is a coordinate axis in the long direction of a base material that is the first direction. Y axis is a coordinate axis in the short direction of the base material. Z axis is a coordinate axis in the thickness direction of the base material. Also, in those figures, the same components are given the same codes.

### <1> First Embodiment

### <1-1> Semiconductor Device 10

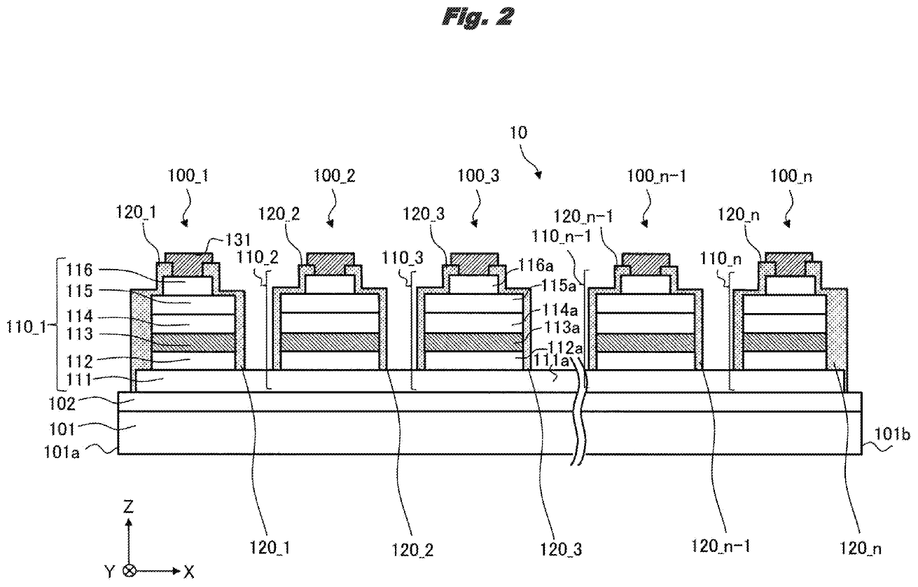

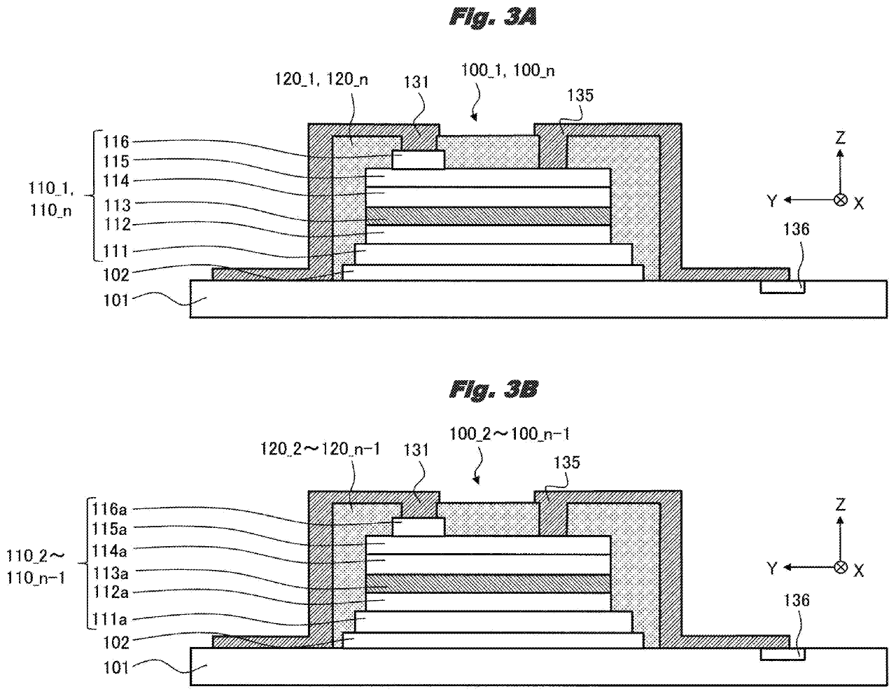

FIG. 1 is a plan view showing schematically the configuration of a semiconductor device 10 of the first embodiment. The semiconductor 10 is a light emitting element array chip. FIG. 2 is a diagram showing schematically a cross section along a line S2-S2 of the semiconductor device 10 in FIG. 1. FIG. 3A is a diagram showing schematically a cross section along a line S3a-S3a of the semiconductor device 10 in FIG. 1, and FIG. 3B is a diagram schematically showing a cross section along a line S3b-S3b of the semiconductor device 10 in FIG. 1.

The semiconductor device 10 has abase material 101, a flattening layer 102 formed on the base material 101, and multiple light emitting elements 100_1˜100_n. n is an integer of 2 or greater. In the first embodiment, the multiple light emitting elements 100_1˜100_n are multiple light emitting thyristors as multiple 3-terminal light emitting elements.

The multiple light emitting elements 100_1˜100_n are disposed on the base material 101 through the flattening layer 102. The multiple light emitting elements 100_1˜100_n are disposed regularly spaced with intervals (e.g., with equal intervals) in the X-axis direction that is the long direction of the base material 101. Inside the base material 101 beneath the flattening layer 102, a drive IC that is an integrated circuit to drive the multiple light emitting elements 100_1˜100_n can be provided. On the base material 101, multiple electrode pads 137 and electrode wirings (not shown) are provided. The base material 101 is formed of Si (silicon) for example. The base material 101 can be formed of a material other than Si, such as glass, ceramic, plastic, or metal.

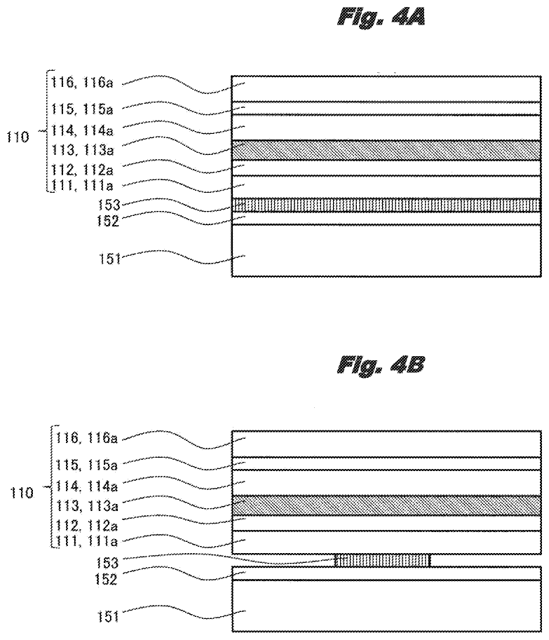

The flattening layer 102 has its surface flattened. The flattening layer 102 is formed, for example, of an organic film, an inorganic film, a metal, or the like. Surface roughness of the flattening layer 102 should desirably be 10 nm or smaller. Bonded on the surface of the flattening layer 102 is a semiconductor thin film 110 (shown in FIGS. 4A and 4B below) that is a semiconductor multilayer structure. The semiconductor thin film 110 is, for example, an epitaxially grown film having multiple semiconductor layers. Note that if the surface roughness of the base material 101 is sufficiently small, the semiconductor film 110 can be directly bonded on the surface of the base material 101 without the flattening layer 102 provided.

### <1-2> Manufacturing of Semiconductor Multilayer Structures 110_1˜110_n

FIGS. 4A and 4B are cross-sectional views showing schematically the manufacturing process of the semiconductor thin film 110 that is the basis of semiconductor multilayer structures 110_1˜110_n of the semiconductor device 10 of the first embodiment. FIG. 4A shows the formation process of the semiconductor thin film 110, and FIG. 4B shows the peeling process of the semiconductor thin film 110. Used as component materials of individual layers of the semiconductor thin film 110 are, for example, GaAs-based semiconductors such as AlGaAs (aluminum gallium arsenide) and GaAs (gallium arsenide).

As shown in FIG. 4A, first formed on a growth base material 151 that is a base material is a buffer layer 152 for growing the semiconductor thin film 110. Next, formed is a sacrificial film 153 that becomes an etching layer for peeling the semiconductor thin film 110 from the growth base material 151. The growth base material 151 is an N-type GaAs (gallium arsenide) layer with Si as a dopant for example, and has a thickness of 550 μm for example. The buffer layer 152 is an N-type GaAs layer with Si as a dopant for example, and has a thickness of 0.20 μm for example. The sacrificial layer 153 is an N-type AlAs (aluminum arsenide) layer with Si as a dopant for example, and has a thickness of 0.05 μm for example.

As shown in FIG. 4A, the semiconductor thin film 110 has, for example, an N-type GaAs layer (cathode layer 111 or 11a), an N-type AlGaAs layer (lower clad layer 112 or 112a), an N-type AlGaAs layer (light emitting layer 113 or 113a), a P-type AlGaAs layer (upper clad layer 114 or 114a), an N-type AlGaAs layer (gate layer 115 or 115a), and a P-type GaAs layer (anode layer 116 or 116a) stacked sequentially from the growth base material 151 side. The light emitting layer 113 is a layer having a smaller band gap than the lower clad layer 112 or the upper clad layer 114.

Next, as shown in FIG. 4B, by selectively etching the sacrificial layer 153, the semiconductor thin film 110 is made separable (peelable) from the buffer layer 152 on the growth base material 151. By performing a selective wet etching with an etchant having a faster etching rate than the semiconductor thin film 110, the sacrificial 153 goes through a state in the middle of etching shown in FIG. 4B and becomes peelable. If using AlAs for the sacrificial layer 153 and a GaAs-based material for the semiconductor thin film 110, etching can be performed with HCl. Next, while holding the semiconductor thin film 110 with a holding device (unshown), the semiconductor thin film 110 is separated from the growth base material 151. Next, the separated semiconductor thin film 110 is placed on the flattening layer 102 of a base material part 150 different from the growth base material 151. The semiconductor thin film 110 is bonded with the flattening layer 102 of the base material part 150 by intermolecular forces for example.

After bonding the semiconductor thin film 110 onto the flattening layer 102, by performing publicly-known photolithography and etching processes, the semiconductor multilayer structures 110_1˜110_n that are separate mesa-shaped element structures shown in FIGS. 2, 3A, and 3B are formed from the semiconductor thin film 110. In other words, the semiconductor multilayer structures 110_1˜110_n of the light emitting elements 100_1˜100_n shown in FIGS. 2, 3A, and 3B are formed from the semiconductor thin film 110. As shown in FIGS. 2 and 3A, the semiconductor multilayer structures 110_1 and 110_n of the light emitting elements 100_1 and 100_n at both ends of the array each have, for example, the N-type cathode layer 111, the N-type lower clad layer 112, the N-type light emitting layer 113, the P-type upper clad layer 114, the N-type gate layer 115, and the P-type anode layer 116. Also, as shown in FIGS. 2 and 3B, the semiconductor multilayer structures 110_2˜110_n−1 of the light emitting elements 100_2˜100_n−1 other than those at both ends of the array each have, for example, the N-type cathode layer 111a, the N-type lower clad layer 112a, the N-type light emitting layer 113a, the P-type upper clad layer 114a, the N-type gate layer 115a, and the P-type anode layer 116a. Note that the semiconductor multilayer structures 110_1˜110_n are not limited to the above-mentioned structures.

Afterwards, organic insulating films 120_1˜120_n are formed covering the semiconductor multilayer structures 110_1˜110_n. The organic insulating films 120_1˜120_n are formed of polyimide for example. The organic insulating films 120_1˜120_n are formed by applying a material substance (e.g., polyamic acid) and processing it using the photolithography technique. Also, the organic insulating films 120_1˜120_n can be formed by applying a material substance and processing it using the dry etching technique.

Afterwards, with lead-out wirings 131, 133, and 135 made of metal, alloy, or the like, the anode layer 116 (or 116a), the gate layer 115 (or 115a) and the cathode layer 111 (or 111a) are respectively connected to an anode connection pad 132 (FIG. 1), a gate connection pad 136, and a cathode connection pad 134 (FIG. 1). The anode connection pad 132 (FIG. 1), the gate connection pad 136, the cathode connection pad 134 (FIG. 1), and the lead-out wirings 131, 133, and 135 are formed by vapor coating or sputtering for example. Before forming the lead-out wirings 131, 133, and 135, the organic insulating films 120_1˜120_n are formed lest the wirings touch except at connection points. Polyimide is used for the organic insulating films 120_1˜120_n, and they are formed so that element widths WA and WB of all the light emitting elements 100_1˜100_n become equal.

Also, although explained in the first embodiment is a structure where the cathode layers 111 or 111a of the light emitting elements 100_1˜100_n of the semiconductor device 10 are connected with one another, a structure where the cathode layers 111 or 111a of the light emitting elements are separated from one another can be adopted.

Also, although the first embodiment has a structure where one cathode connection pad 134 is shared by two light emitting elements adjacent in the X-axis direction, a cathode connection pad 134 can be formed for each light emitting element, or one cathode connection pad 134 can be shared by three or more light emitting elements.

### <1-3> Structure of Light Emitting Elements 100_1˜100_n

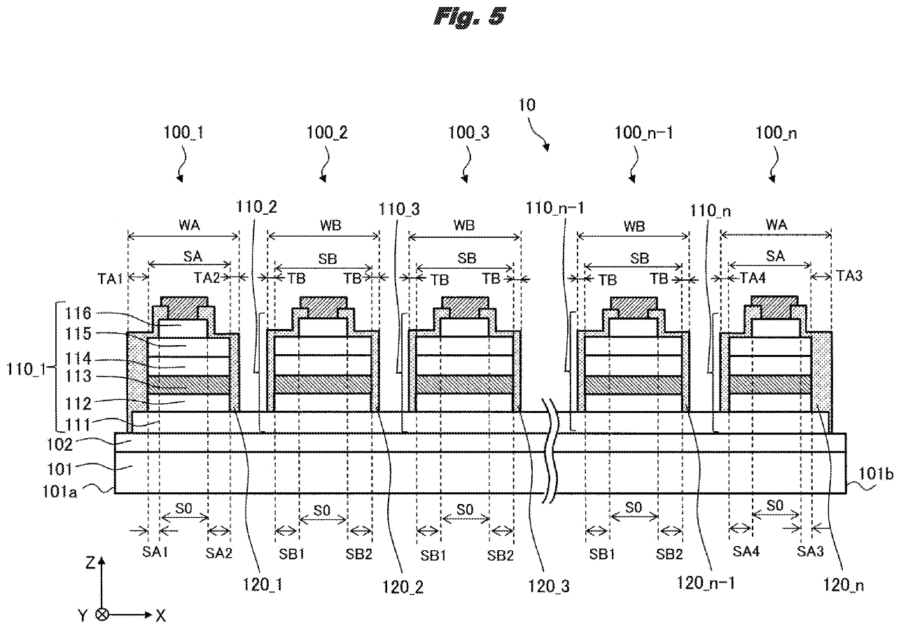

FIG. 5 is a cross-sectional view showing the sizes of individual parts of the semiconductor device 10 of the first embodiment. Among the multiple light emitting elements 100_1˜100_n, the light emitting element 100_1 as a first light emitting element closest to a base material end part 101a that is one end part in the X-axis direction of the base material 101 has the semiconductor multilayer structure 110_1 as a first semiconductor multilayer structure and the organic insulating film 120_1 as a first organic insulating film covering at least the side faces of the semiconductor multilayer structure 110_1 in the X-axis direction. In the same manner, the light emitting element 100_n as a first light emitting element closest to a base material end part 101b that is the other end part in the X-axis direction of the base material 101 has the semiconductor multilayer structure 110_n as a first semiconductor multilayer structure and the organic insulating film 120_n as a first organic insulating film covering at least the side faces of the semiconductor multilayer structure 110_n in the X-axis direction. Note that the light emitting elements 100_1 and 100_n are also called array-end light emitting elements.

The light emitting elements 100_2˜100_n−1 as second light emitting elements that are light emitting elements other than the array-end light emitting elements 100_1 and 100_n have the semiconductor multilayer structures 110_2˜110_n−1 as second semiconductor multilayer structures and the organic insulating films 120_2˜120_n−1 as second organic insulating films covering at least the side faces of the semiconductor multilayer structures 110_2˜110_n−1 in the X-axis direction. The light emitting elements 100_2˜100_n−1 are also called non-array-end light emitting elements.

A multilayer structure width SA that is the X-axis direction width of the semiconductor multilayer structures 110_1 and 110_n of the array-end light emitting elements 100_1 and 100_n is smaller than a multiplayer structure width SB that is the X-axis direction width of the semiconductor multilayer structures 110_2˜110_n−1 of the non-array-end light emitting elements 100_2˜100_n−1. This is for making the amount of light emission of each of the array-end light emitting elements 100_1 and 100_n closer to the amount of light emission of each of the non-array-end light emitting elements 100_2˜100_n−1.

Also, a film thickness TA1 as a first film thickness that is the thickness of part of the organic insulating film 120_1 covering the side face of the semiconductor multilayer structure 110_1 on the side closest to the base material end part 101a is greater than a film thickness TB as a second film thickness that is the thickness of portions of the organic insulating films 120_2˜120_n−1 covering the side faces (or close side faces) of the semiconductor multilayer structures 110_2˜110_n−1 on the side closest to the base material end part 101a. In the same manner, a film thickness TA3 as a first film thickness that is the thickness of a portion of the organic insulating film 120_n covering the side face (or close side face) of the semiconductor multilayer structure 110_n on the side closest to the base material end part 101b is greater than the film thickness TB that is the thickness of parts of the organic insulating films 120_2˜120_n−1 covering the side faces of the semiconductor multilayer structures 110_2˜110_n−1 on the side closest to the base material end part 101b.

The element width (first element width) WA that is the X-axis direction width of the array-end light emitting elements 100_1 and 100_n is nearly equal to the element width (second element width) WB that is the X-axis direction width of the light emitting elements 100_2˜100_n−1. If the organic insulating films 120_1 and 120_n have parts (first portions) covering the upper face of the semiconductor multilayer structures 110_1 and 110_n, respectively, the element width WA is the X-axis direction width of the parts covering the upper faces of the semiconductor multilayer structures 110_1 and 110_n. If the organic insulating films 120_2˜120_n−1 have parts (second portions) covering the upper faces of the semiconductor multilayer structures 110_2˜110_n−1, respectively, the element width WB is the X-axis direction width of the parts covering the upper faces of the semiconductor multilayer structures 110_2˜110_n−1. The element width WA should desirably be within a range of 10% of the element width WB. The element width WA should more desirably be within a range of 5% of the element width WB.

Also, the film thickness TA1 is greater than a film thickness TA2 as a third film thickness that is the thickness of a portion of the organic insulating film 120_1 covering the side face (or farther side face) of the semiconductor multilayer structure 110_1 on the side farthest from the base material end part 101a. In the same manner, the film thickness TA3 is greater than a film thickness TA4 as a third film thickness that is the thickness of part of the organic insulating film 120_n covering the side face of the semiconductor multilayer structure 110_n on the side farthest from the base material end part 101b. This is for making the light emission shape of each of the array-end light emitting elements 100_1 and 100_n equivalent to the light emission shape of each of the non-array-end light emitting elements 100_2˜100_n−1 even if the multilayer structure width SA of the semiconductor multilayer structures 110_1 and 110_n is made smaller than the multilayer structure width SB of the semiconductor multilayer structures 110_2˜110_n−1. That is, for uniformizing the light emission shapes.

In the first embodiment, the semiconductor multilayer structures 110_1 and 110_n of the array-end light emitting elements 100_1 and 100_n have the first semiconductor layer (e.g., the cathode layer 111, the lower clad layer 112, and the light emitting layer 113) of a first conductive type, the second semiconductor layer (e.g., the upper clad layer 114) of a second conductive type that is different from the first conductive type, the third semiconductor layer (e.g., the gate layer 115) of the first conductive type, and the fourth semiconductor layer (e.g., the anode layer 116) of the second conductive type, stacked sequentially from the base material 101 side. Also, the semiconductor multilayer structures 110_2˜110_n−1 of the non-array end light emitting elements 100_2˜100_n−1 have the fifth semiconductor layer (e.g., the cathode layer 111a, the lower clad layer 112a, and the light emitting layer 113a) of the first conductive type, the sixth semiconductor layer (e.g., the upper clad layer 114a) of the second conductive type, the seventh semiconductor layer (e.g., the gate layer 115a) of the first conductive type, and the eighth semiconductor layer (e.g., the anode layer 116a) of the second conductive type, stacked sequentially from the base material 101 side. In FIG. 5, the first conductive type is the N type, and the second conductive type is the P type. Note that this invention is also applicable to a semiconductor device where the first conductive type is the P type, and the second conductive type is the N type.

Also, in the first embodiment, a first distance SA1 between a first face including the end face (that is, the side face) of the third semiconductor layer (e.g., the gate layer 115) on the side closest to the base material end part 101a and a second face including the end face (that is, the side face) of the fourth semiconductor layer (e.g., the anode layer 116) on the side closest to the base material end part 101a is smaller than a second distance SA2 between a third face including the end face (that is, the side face) of the third semiconductor layer (e.g., the gate layer 115) on the side farthest from the base material end part 101a and a fourth face including the end face (that is, the side face) of the fourth semiconductor layer (e.g., the anode layer 116) on the side farthest from the base material end part 101a. In the same manner, a first distance SA3 between a first face including the end face (that is, the side face) of the third semiconductor layer (e.g., the gate layer 115) on the side closest to the base material end part 101b and a second face including the end face (that is, the side face) of the fourth semiconductor layer (e.g., the anode layer 116) on the side closest to the base material end part 101b is smaller than a second distance SA4 between a third face including the end face (that is, the side face) of the third semiconductor layer (e.g., the gate layer 115) on the side farthest from the base material end part 101b and a fourth face including the end face (that is, the side face) of the fourth semiconductor layer (e.g., the anode layer 116) on the side farthest from the base material end part 101b.

Also, a distance SB1 between a fifth face including the end face of the seventh semiconductor layer (e.g., the gate layer 115a) on one side in the X-axis direction and a sixth face including the end face of the eighth semiconductor layer (e.g., the anode layer 116a) on the above-mentioned side is equal to a distance SB2 between a seventh face including the end face of the seventh semiconductor layer (e.g., the gate layer 115a) on the other side opposite to the above-mentioned side and an eighth face including the end face of the eighth semiconductor layer (e.g., the anode layer 116a) on the above-mentioned other side. Furthermore, the second distances SA2 and SA4 are equal to each other and equal to the third distance SB1 and the fourth distance SB2. Note that S0 is the X-axis direction width of the anode layers 116 and 116a.

Note that examples of dimensions of the individual parts in FIG. 5 are as follows:

SA=13.5±1.5 μm

SA1=SA3=4.0±0.5 μm

SA2=SA4=5.0±0.5 μm

TA1=TA3=1.5±0.2 μm

TA2=TA4=0.5±0.2 μm

SB=14.5±1.5 μm

SB1=5.0±0.5 μm

SB2=5.0±0.5 μm

TB=0.5±0.2 μm

Although in FIG. 1, the lead-out wiring 135 is connected to the N-type gate layer 115 or 115a, the semiconductor layer between the N-type gate layer 115 or 115a and the light emitting layer 113 or 113a (e.g., the layer in the position of the upper clad layer 114 or 114a) can be made a P-type gate layer, and the lead-out wiring 135 can be connected to this P-type gate layer. In this case, the first distances SA1 and SA3, see FIG. 5, between the first face including the end face of the second semiconductor layer (114) on the side closest to the base material end part 101a or 101b and the second face including the end face of the anode layer 116 that is the fourth semiconductor layer on the side closest to the above-mentioned base material end part 101a or 101b become smaller than the second distances SA2 and SA4 between the third face including the end face of the second semiconductor layer (114) on the side farthest from the base material end part 101a or 101b and the fourth face including the end face of the anode layer 116 on the side farthest from the base material end part 101a or 101b, respectively. Also, the third distance SB1 between the fifth face including the end face of the sixth semiconductor layer (114a) on one side in the X-axis direction and the sixth face including the end face of the anode layer 116a that is the eighth semiconductor layer on the above-mentioned side is equal to the fourth distance SB2 between the seventh face including the end face of the sixth semiconductor layer (114a) on the other side opposite to the above-mentioned side and the eighth face including the end face of the anode layer 116a on the above-mentioned other side. Also, the second distances SA2 and SA4 are equal to the third distance SB1.

### <1-4> Actions of First Embodiment

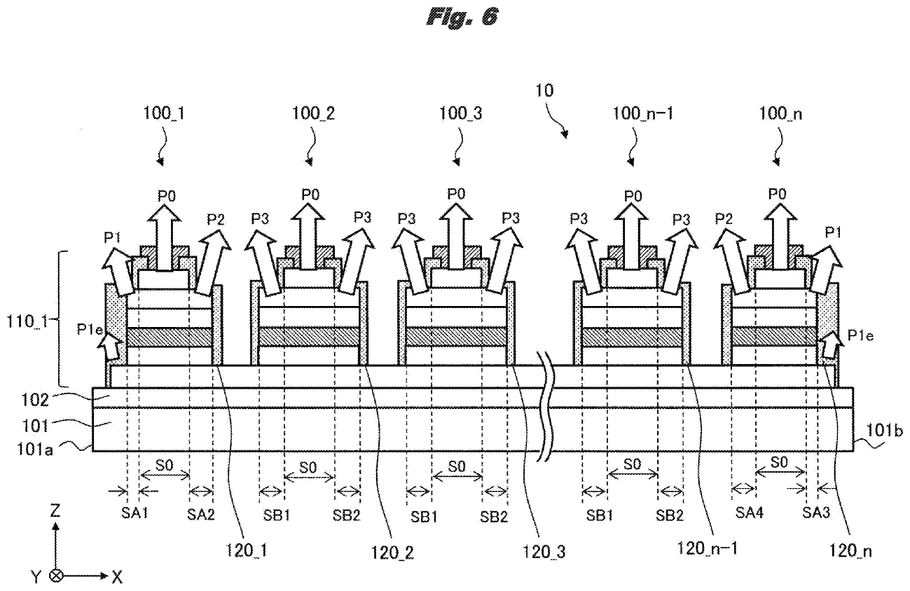

FIG. 6 is a diagram showing light beams emitted from the light emitting elements 100_1˜100_n of the semiconductor device 10 of the first embodiment. Light beams emitted from each of the non-array-end light emitting elements 100_2˜100_n−1 are shown as arrows P0, P3, and P3. If P0 denotes the amount of light emitted through the anode layer 116a, and two P3s the amounts of light emitted through the outside of the anode layer 116a, the amount of light emitted from one of the non-array-end light emitting elements 100_2˜100_n−1 is expressed as (P0+P3+P3).

Also, light beams emitted from each of the array-end light emitting elements 100_1 and 100_n are shown as arrows P0, P2, P1, and P1e. If P0 denotes the amount of light emitted through the anode layer 116, P2 and P1 the amounts of light emitted through the outside of the anode layer 116, and P1e the amount of light emitted from the end part vicinity of the cathode layer 111 of the semiconductor multilayer structure 110_1 or 110_n, the amount of light emitted from one of the light emitting elements 100_1 and 100_n is expressed as (P0+P2+P1+P1e).

In general, in the array-end light emitting elements 100_1 and 100_n, because the emitted light beam P1e from the end part vicinity of the cathode layer 111 is added, the amount of light becomes greater than that of each of the non-array-end light emitting elements 100_2˜100_n−1, thereby the amounts of light emitted from the light emitting elements 100_1˜100_n do not become uniform. However, in the first embodiment, by forming the multilayer structure width SA that is the width of the semiconductor multilayer structures 110_1 and 110_n of the array-end light emitting elements 100_1 and 100_n smaller than the multilayer structure width SB that is the width of the semiconductor multilayer structures 110_2˜110_n−1 of the non-array-end light emitting elements 100_2˜100_n−1,

(P0+P3+P3)=(P0+P2+P1+P1e)

is achieved. Therefore, the amounts of light emitted from the light emitting elements 100_1˜100_n are uniformized.

Also, the XY-plane shapes of light emitted from the light emitting layers 113 and 113a correspond to the XY-plane shapes of the organic insulating films 120_1˜120_n. Therefore, the organic insulating films 120_1˜120_n are formed so that the element width WA of the light emitting elements 100_1 and 100_n including the organic insulating films 120_1 and 120_n becomes nearly equal to the element width WB of the light emitting elements 100_2˜100_n−1 including the organic insulating films 120_2˜120_n−1. That is, in the first embodiment, while making the multilayer structure width SA of the array-end light emitting elements 100_1 and 100_n smaller than the multilayer structure width SB of the non-array-end light emitting elements 100_2˜100_n−1 for uniformizing the amounts of light of the light emitting elements 100_1˜100_n, the element width WA of the array-end light emitting elements 100_1 and 100_n is made nearly equal to the element with WB of the non-array-end light emitting elements 100_2˜100_n−1 for uniformizing the light emission shapes.

### <1-5> Comparative Example 1

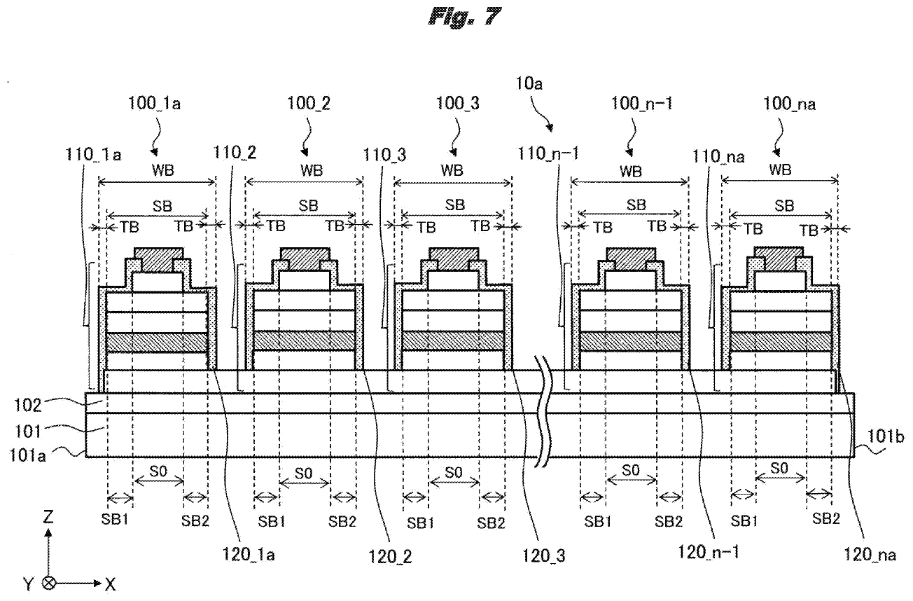

FIG. 7 is a cross-sectional view showing schematically the configuration of a semiconductor device 10a of Comparative Example 1. In Comparative Example 1, light emitting elements 100_1a, 100_2˜100_n−1, and 100_na have mutually the same shape. That is, semiconductor multilayer structures 110_1a, 110_2˜110_n−1, and 110_na of the light emitting elements 100_1a, 100_2˜100_n−1, and 100_na are mutually identical, and organic insulating films 120_1a, 120_2˜120_n−1, and 120_na have mutually the same shape. Therefore, element widths WB of the light emitting elements 100_1a, 100_2˜100_n−1, and 100_na are mutually the same, multilayer structure widths SB of the semiconductor multilayer structures 110_1a, 110_2˜110_n−1, and 110_na are mutually the same, and film thicknesses TB of the organic insulating films 120_1a, 120_2˜120_n−1, and 120_na are mutually the same.

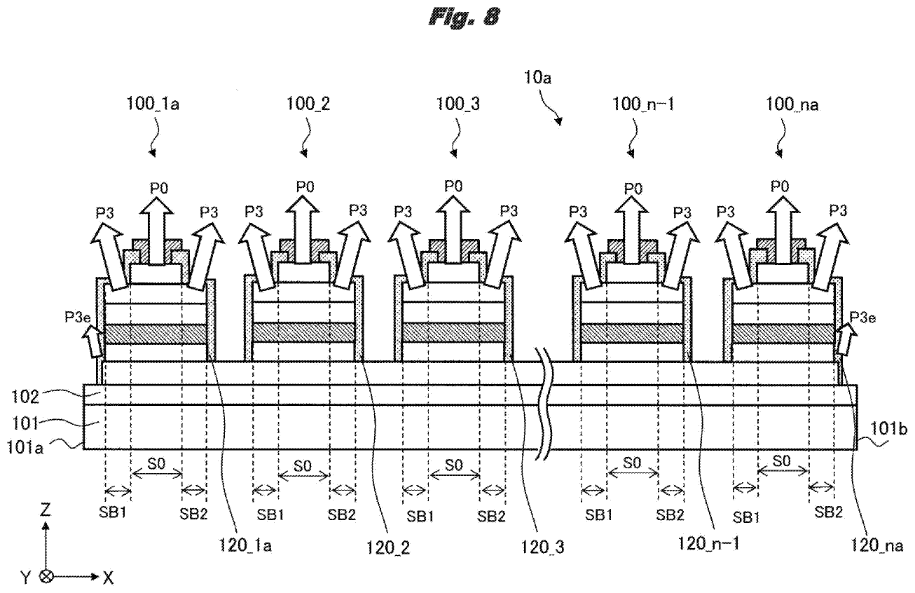

FIG. 8 is a diagram showing light beams emitted from the light emitting elements 100_1a, 100_2˜100_n−1, and 100_na of the semiconductor device 10a of Comparative Example 1. Light beams emitted from the light emitting elements 100_1a and 100_na are shown as arrows P0, P3, P3, and P3e. If P0 denotes the amount of light emitted through an anode layer 116, and two P3s the amounts of light emitted through the outside of the anode layer 116, the amount of light emitted from one of the light emitting elements 100_1a and 100_na is expressed as (P0+P3+P3+P3e).

Also, light beams emitted from the non-array-end light emitting elements 100_2˜100_n−1 are shown as arrows P0, P3, and P3. If P0 denotes the amount of light emitted through an anode layer 116a, and two P3s the amounts of light emitted through the outside of the anode layer 116a, the amount of light emitted from one of the light emitting elements 100_2˜100_n−1 is expressed as (P0+P3+P3).

In this manner, in each of the array-end light emitting elements 100_1a and 100_na of Comparative Example 1, because a light beam P3e emitted from an edge part of a cathode layer 111 is added, the amount of light becomes (P0+P3+P3+P3e) that is greater than the amount of light (P0+P3+P3) of each of the non-array-end light emitting elements 100_2˜100_n−1. That is, in Comparative Example 1, the amounts of light emitted from the light emitting elements 100_1a, 100_2-100_n−1, and 100_na become nonuniform.

### <1-6> Comparative Example 2

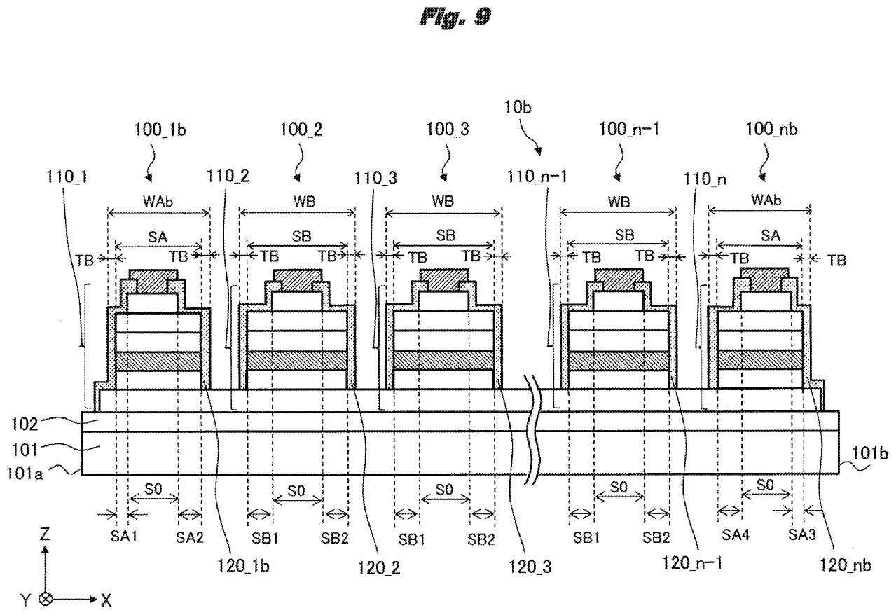

FIG. 9 is a cross-sectional view showing schematically the configuration of a semiconductor device 10b of Comparative Example 2. In Comparative Example 2, array-end light emitting elements 100_1b and 100_nb have mutually the same shape that is different from that of non-array-end light emitting elements 100_2˜100_n−1. That is, semiconductor multilayer structures 110_1b and 110_nb of the array-end light emitting elements 100_1b and 100_nb have a different shape from that of semiconductor multilayer structures 110_2˜110_n−1 of the non-array end light emitting elements 100_2˜100_n−1, and the thicknesses of organic insulating films 120_1b, 120_2˜120_n−1, and 120_nb are mutually the same. In this manner, in Comparative Example 2, a multilayer structure width SA of the semiconductor multilayer structures 110_1b and 110_nb is smaller than a multilayer structure width SB of the semiconductor multilayer structures 110_2˜110_n−1, film thicknesses TB of the organic insulating films 120_1b, 120_2˜120_n−1, and 120_nb are mutually the same, and an element width WAb of the array-end light emitting elements 100_1b and 100_nb is smaller than an element width WB of the non-array-end light emitting elements 100_2˜100_n−1.

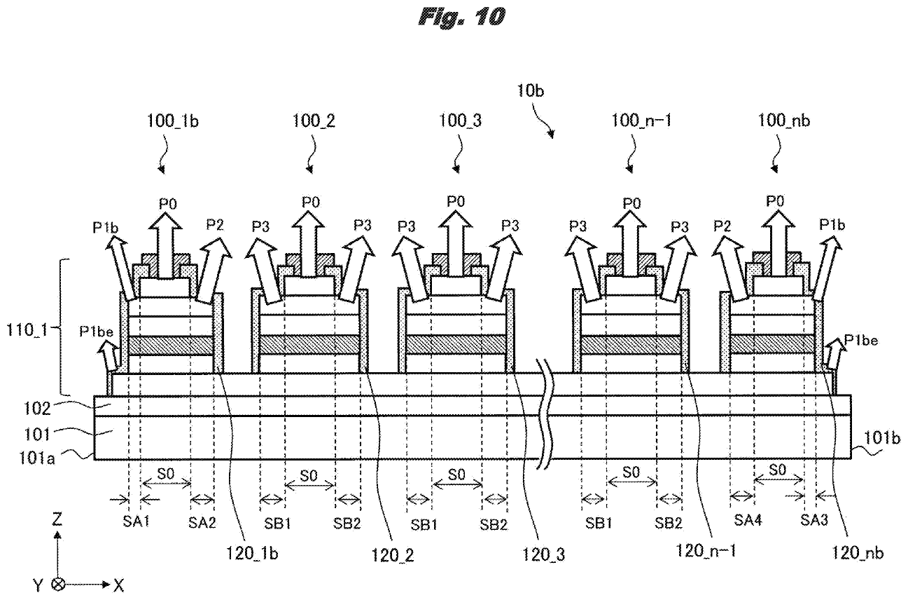

FIG. 10 is a diagram showing light beams emitted from the light emitting elements 100_1b, 100_2˜100_n−1, and 100_nb of the semiconductor device 10b of Comparative Example 2. Light beams emitted from the light emitting elements 100_1b and 100_nb are shown as arrows P0, P2, P1b, and P1be. If P0 denotes the amount of light emitted through an anode layer 116, P2 and P1b the amounts of light emitted through the outside of the anode layer 116, and P1be the amount of light emitted from an end part of a cathode layer 111, the amount of light emitted from one of the array-end light emitting elements 100_1b and 100_nb is expressed as (P0+P2+P1b+P1be).

Also, light beams emitted from the non-array-end light emitting elements 100_2˜100_n−1 are shown as arrows P0, P3, and P3. If P0 denotes the amount of light emitted through an anode layer 116a, and two P3s the amounts of light emitted through the outside of the anode layer 116a, the amount of light emitted from one of the light emitting elements 100_2˜100_n−1 is expressed as (P0+P3+P3).

In this manner, although the amount of light of each of the array-end light emitting elements 100_1b and 100_nb of Comparative Example 2 becomes (P0+P2+P1b+P1be) that is nearly equal to the amount of light of each of the non-array-end light emitting elements 100_2˜100_n−1, the light emission shape of the array-end light emitting elements 100_1b and 100_nb becomes smaller than the light emission shape of the non-array-end light emitting elements 100_2˜100_n−1. That is, in Comparative Example 2, the light emission shape of the light emitting elements 100_1b and 100_nb and the light emission shape of the light emitting elements 100_2˜100_n−1 become nonuniform.

### <1-7> Efficacy of First Embodiment

As explained above, according to the first embodiment, while making the multilayer structure width SA of the semiconductor multilayer structures 110_1 and 110_n of the array-end light emitting elements 100_1 and 100_n smaller than the multilayer structure width SB of the semiconductor multilayer structures 110_2˜110_n−1 of the non-array-end light emitting elements 100_2˜100_n−1, the sizes of the organic insulating films 120_1˜120_n covering the semiconductor multilayer structures 110_1˜110_n are adjusted, thereby the amounts of emitted light and light emission shapes of the array-end light emitting elements 100_1 and 100_n and the non-array-end light emitting elements 100_2˜100_n−1 become uniform. Also, by the amounts of emitted light becoming uniform, drive currents inside a light emitting thyristor array become uniform, and over-time changes by a continuous operation become identical, improving reliability. Also, by the light emission shapes becoming uniform, when mounting a light emitting array chip provided with the light emitting thyristor array on an optical print head, an improvement in print quality can be expected.

### <1-8> Modification Example>

Although exampled above were examples where the semiconductor multilayer structures 110_1˜110_n had semiconductor layers structured as PNPN sequentially from the base material 101 side, the semiconductor multilayer structures 110_1˜110_n can have semiconductor layers structured as NPNP sequentially from the base material 101 side.

Also, although explained above were examples where the light emitting elements 100_1˜100_n were light emitting elements, the light emitting elements 100_1˜100_n can be light emitting diodes having an NPN semiconductor structure or a PNP semiconductor structure.

### <2> Second Embodiment

FIG. 11 is a perspective view showing the structure of the main part of an optical print head of the second embodiment. As shown in FIG. 11, a substrate unit that is the main part of the optical print head has a printed wiring board 201 that is a mounting substrate (or mounting board), and multiple semiconductor devices 10 disposed in an array. The semiconductor devices 10 are fixed with a thermosetting resin or the like onto the printed wiring board 201 that is a COB (Chip On Board) substrate. Electrode pads 137 for external connections of the semiconductor devices 10 and connection pads 202 of the printed wiring board 201 are electrically connected via bonding wires 203. Also, various wiring patterns, electronic parts, connectors, etc. can be mounted on the printed wiring board 201.

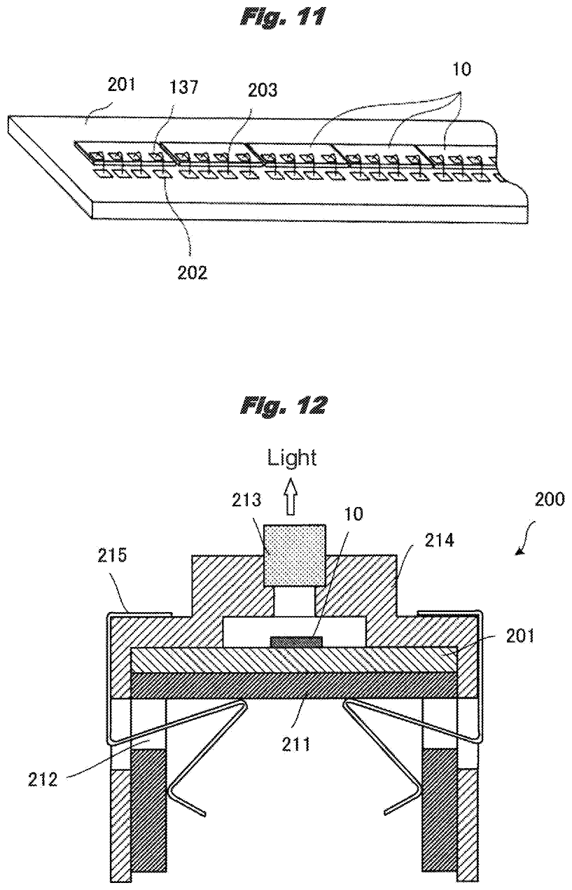

FIG. 12 is a cross-sectional view showing the structure of the optical print head 200 of the second embodiment. The optical print head 200 is an exposure device of an electrophotographic image forming apparatus. As shown in FIG. 12, the optical print head 200 is provided with a base member 211, the printed wiring board 201, the semiconductor devices 10, a lens array 213 including multiple erect equal-magnification imaging lenses, lens holders 214, and clampers 215 that are spring members. The base member 211 is a member for fixing the printed wiring board 201. Installed on the side faces of the base member 211 are opening parts 212 for fixing the printed wiring board 201 and the lens holders 214 on the base member 211 using the clampers 215. The lens holders 214 are formed by injection-molding an organic polymer material for example. The lens array 213 is an optical lens group that forms an image of light beams emitted from the semiconductor devices 10 on a photosensitive drum as an image carrier. The lens holders 214 hold the lens array 213 on a prescribed position of the base member 211. The clampers 215 nip-hold the individual components through the opening parts 212 of the base member 211 and opening parts of the lens holders 214.

On the print head 200, light emitting elements on the semiconductor devices 10 selectively emit light according to print data. Light beams emitted from the light emitting elements form an image through the lens array 213 on the photosensitive drum that is uniformly charged. Thereby, an electrostatic latent image is formed on the photosensitive drum, and afterwards through a development process, a transfer process, and a fusing process, an image made of a developer is formed on a print medium (sheet).

As explained above, because the optical print head 200 of the second embodiment is provided with the semiconductor devices 10 that can uniformize the amounts of emitted light of the multiple light emitting elements and uniformize the light emission shapes of the multiple light emitting elements, by building this into an image forming apparatus, print quality can be improved.

### <3> Third Embodiment

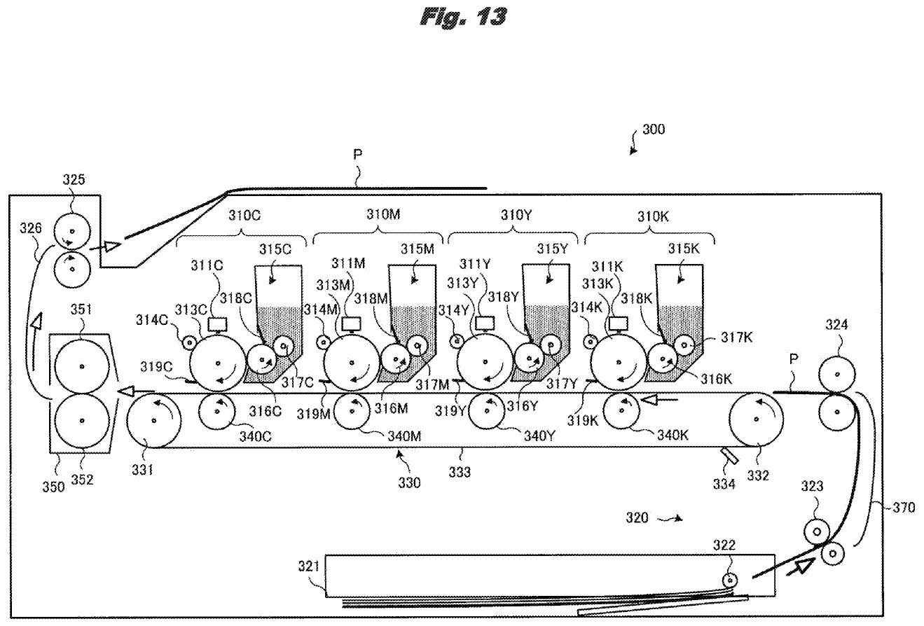

FIG. 13 is a cross-sectional view showing schematically the configuration of an image forming apparatus 300 of the third embodiment. The image forming apparatus 300 is, for example, a color printer utilizing an electrophotographic process.

As shown in FIG. 13, the image forming apparatus 300 has, as its main components, image forming parts (that is, processing units) 310K, 310Y, 310M, and 310C that form toner images (that is, developer images) on a recording medium P such as a sheet through an electrophotographic process, a medium supply part 320 that supplies the recording medium P to the image forming parts 310K, 310Y, 310M, and 310C, a carrying part 330 that carries the recording medium P, transfer rollers 340K, 340Y, 340M, and 340C as transfer parts disposed so as to correspond to the image forming parts 310K, 310Y, 310M, and 310C, respectively, a fuser 350 that fuses the toner images transferred onto the recording medium P, and a guide 326 and an ejection roller pair 325 as a medium ejecting part that ejects the recording medium P that passed through the fuser 350 to the outside of a chassis of the image forming apparatus 300. The number of the image forming parts of the image forming apparatus 300 can be 3 or smaller or 5 or greater. Also, the image forming apparatus 300 can be a monochrome printer whose number of image forming parts is 1 as far as it forms an image on the recording medium P through an electrophotographic process.

As shown in FIG. 13, the medium supply part 320 has a medium cassette 321, a hopping roller 322 that feeds out the recording medium P stacked inside the medium cassette 321 by one piece at a time, a roller pair 323 that carries the recording medium P fed out from the medium cassette 321, a guide 370 that guides the recording medium P, and registration rollers/pinch rollers 324 that corrects skew of the recording medium P.

The image forming parts 310K, 310Y, 310M, and 310C form black (K), yellow (Y), magenta (M), and cyan (C) toner images on the recording medium P, respectively. The image forming parts 310K, 310Y, 310M, and 310C are arranged along a medium carrying route from the upstream side to the downstream side in the medium carrying direction (that is, from the right to the left in FIG. 1). Each of the image forming parts 310K, 310Y, 310M, and 310C can be a freely-detachable unit. The image forming parts 310K, 310Y, 310M, and 310C basically have the same structure except having different colors of toners accommodated.

The image forming parts 310K, 310Y, 310M, and 310C have optical print heads 311K, 311Y, 311M, and 311C as exposure devices for individual colors, respectively. Each of the optical print heads 311K, 311Y, 311M, and 311C is the optical print head 200 of the second embodiment.

The image forming parts 310K, 310Y, 310M, and 310C have photosensitive drums 313K, 313Y, 313M, and 313C as image carriers supported rotatably, charging rollers 314K, 314Y, 314M, and 314C as charging members that uniformly charge the surfaces of the photosensitive drums 313K, 313Y, 313M, and 313C, and development parts 315K, 315Y, 315M, and 315C that form electrostatic latent images on the surfaces of the photosensitive drums 313K, 313Y, 313M, and 313C with exposures by the optical print heads 311K, 311Y, 311M, and 311C and afterwards supply toners onto the surfaces of the photosensitive drums 313K, 313Y, 313M, and 313C to form toner images corresponding to the electrostatic latent images.

The development parts 315K, 315Y, 315M, and 315C have toner accommodating parts as developer accommodating parts that form developer accommodating spaces to accommodate toners, development rollers 316K, 316Y, 316M, and 316C as developer carriers that supply toners onto the surfaces of the photosensitive drums 313K, 313Y, 313M, and 313C, supply rollers 317K, 317Y, 317M, and 317C that supply toners accommodated inside the toner accommodating parts to the development rollers 316K, 316Y, 316M, and 316C, and development blades 318K, 318Y, 318M, and 318C as toner regulating members that regulate the thickness of toner layers on the surfaces of the development rollers 316K, 316Y, 316M, and 316C.

Exposures by the optical print heads 311K, 311Y, 311M, and 311C are executed based on image data for printing on the surfaces of the uniformly charged photosensitive drums 313K, 313Y, 313M, and 313C. Each of the optical print heads 311K, 311Y, 311M, and 311C includes a light emitting element array where light emitting elements as multiple light emitting elements are arranged in the axial direction of the photosensitive drum 313K, 313Y, 313M, or 313C.

As shown in FIG. 13, the carrying part 330 has a carrying belt (transfer belt) 333 that adsorbs and carries the recording medium P, a drive roller 331 that is rotated by a drive part and drives the carrying belt 333, and a tension roller (driven roller) 332 that forms a pair with the drive roller 331 to stretch the carrying belt 333.

As shown in FIG. 13, the, transfer rollers 340K, 340Y, 340M, and 340C are disposed opposing the photosensitive drums 313K, 313Y, 313M, and 313C of the image forming parts 310K, 310Y, 310M, and 310C through the carrying belt 333. Toner images formed on the surfaces of the photosensitive drums 313K, 313Y, 313M, and 313C of the image forming parts 310K, 310Y, 310M, and 310C are sequentially transferred by the transfer rollers 340K, 340Y, 340M, and 340C onto the upper face of the recording medium P carried in an arrow direction along the medium carrying route. The image forming parts 310K, 310Y, 310M, and 310C have cleaning devices 319K, 319Y, 319M, and 319C that remove toners remaining on the photosensitive drums 313K, 313Y, 313M, and 313C after transferring the toner images developed on the photosensitive drums 313K, 313Y, 313M, and 313C to the recording medium P.

The fuser 350 has a pair of rollers 351 and 352 pressing against each other. The roller 351 is a roller (a heat application roller) containing a heater inside, and the roller 352 is a pressure application roller pressed against the roller 351. The recording medium P having an unfused toner image pass between the pair of rollers 351 and 352 of the fuser 350. At that time, the unfused toner image is fused onto the recording medium P with heat and pressure applied.

Also, provided on the lower face part of the carrying belt 333 is a cleaning mechanism including a cleaning blade 334 and a waste toner accommodating part (unshown).

During printing, the recording medium P inside the medium cassette 321 is fed out by the hopping roller 322 and sent to the roller pair 323. Subsequently, the recording medium P is sent from the roller pair 323 to the carrying belt 333 via the registration/pinch rollers 324, and carried to the image forming parts 310K, 310Y, 310M, and 310C accompanying the travel of this carrying belt 333. In the image forming parts 310K, 310Y, 310M, and 310C, the surfaces of the photosensitive drums 313K, 313Y, 313M, and 313C are charged by the charging rollers 314K, 314Y, 314M, and 314C, and exposed by the optical print heads 311K, 311Y, 311M, and 311C, respectively, forming electrostatic latent images. On the electrostatic latent images, toners made into thin layers on the development rollers 316K, 316Y, 316M, and 316C electrostatically adhere, forming individual toner color images. The individual color toner images are transferred to the recording medium P by the transfer rollers 340K, 340Y, 340M, and 340C, forming a color toner image on the recording medium P. After the transfer, toners remaining on the photosensitive drums 313K, 313Y, 313M, and 313C are removed by the cleaning devices 319K, 319Y, 319M, and 319C. The recording medium P with the color toner image formed is sent to the fuser 350. In the fuser 350, the color toner image is fused to the recording medium P, forming a color image. The recording medium P with the color image formed is carried along the guide 326, and ejected onto a stacker by the ejection roller pair 325.

As explained above, because the image forming apparatus 300 of the third embodiment utilizes the optical print head 200 of the second embodiment as the optical print heads 311K, 311Y, 311M, and 311C, it can improve print quality by the image forming apparatus 300.

What is claimed is:

1. A semiconductor device, comprising:
a base material, and
a plurality of light emitting elements aligned in a first direction on the base material, wherein
among the light emitting elements, a first light emitting element that is one light emitting element, which is positioned closest to a base material end part that is an end part of the base material in the first direction, is provided with
a first semiconductor multilayer structure and
a first organic insulating film covering at least side faces of the first semiconductor multilayer structure in the first direction,
among the light emitting elements, a second light emitting element that is a different light emitting element from the first light emitting element is provided with
a second semiconductor multilayer structure and
a second organic insulating film covering at least side faces of the second semiconductor multilayer structure in the first direction,
a first multilayer structure width that is the first direction width of the first semiconductor multilayer structure is smaller than a second multilayer structure width that is the first direction width of the second semiconductor multilayer structure,
a first multilayer structure thickness is narrower than a second multilayer structure thickness wherein the first multilayer structure thickness is a thickness of the first semiconductor multilayer structure determined in the first direction, and the second multilayer structure thickness is a thickness of the second semiconductor multilayer structure determined in the first direction, and
a first film thickness is greater than a second film thickness wherein the first film thickness is a thickness of a portion of the first organic insulating film that covers one of the side faces of the first semiconductor multilayer structure, which is closer to the base material end part than the other of the side faces, and the second film thickness is a thickness of a portion of the second organic insulating film that covers one of the side faces of the second semiconductor multilayer structure, which is closer to the base material end part that the other of the side faces.

2. The semiconductor device according to claim 1, wherein
a first element width that is the first direction width of the first light emitting element is ranged within a ±10% range of a second element width that is the first direction width of the second light emitting element.

3. The semiconductor device according to claim 1, wherein
the first film thickness is greater than a third film thickness that is a thickness of a portion of the first organic insulating film that covers the other of the side faces of the first semiconductor multilayer structure, which is farther from the base material end part than the one of the side faces.

4. The semiconductor device according to claim 2, wherein
the first organic insulating film is provided with a first portion covering an upper face of the first semiconductor multilayer structure,
the second organic insulating film is provided with a second portion covering an upper face of the second semiconductor multilayer structure,
the first element width is a width of an upper face of the first portion in the first direction, and
the second element width is a width of an upper face of the second portion in the first direction.

5. The semiconductor device according to claim 1, wherein
the first light emitting element and the second light emitting element are light emitting thyristors.

6. The semiconductor device according to claim 5, wherein
the first semiconductor multilayer structure is provided with
a first semiconductor layer of a first conductive type,
a second semiconductor layer of a second conductive type that is different from the first conductive type,
a third semiconductor layer of the first conductive type, and
a fourth semiconductor layer of the second conductive type wherein the first to fourth semiconductor layers are stacked sequentially in this order on the base material,
the second semiconductor multilayer structure is provided with
a fifth semiconductor layer of the first conductive type,
a sixth semiconductor layer of the second conductive type,
a seventh semiconductor layer of the first conductive type, and
an eighth semiconductor layer of the second conductive type wherein the fifth to eighth semiconductor layers are stacked sequentially in this order on the base material,
a first distance is smaller than a second distance wherein
the first distance is defined between a first face, which includes an end face of the third semiconductor layer on one side close to the base material end part, and a second face, which includes an end face of the fourth semiconductor layer on one side close to the base material end part,
the second distance is defined between a third face, which includes an end face of the third semiconductor layer on one side far from the base material end part, and a fourth face, which includes an end face of the fourth semiconductor layer on one side far from the base material end part,
a third distance is equal to a fourth distance wherein
the third distance is defined between a fifth face, which includes an end face of the seventh semiconductor layer on one side in the first direction, and a sixth face, which includes an end face of the eighth semiconductor layer on the one side, and
the fourth distance is defined between a seventh face, which includes an end face of the seventh semiconductor layer on the other side opposite to the one side, and an eighth face, which includes an end face of the eighth semiconductor layer on the other side, and
the second distance is equal to the third distance.

7. The semiconductor device according to claim 5, wherein
the first semiconductor multilayer structure is provided with
a first semiconductor layer of a first conductive type,
a second semiconductor layer of a second conductive type that is different from the first conductive type,
a third semiconductor layer of the first conductive type, and
a fourth semiconductor layer of the second conductive type wherein the first to fourth semiconductor layers are stacked sequentially in this order on the base material,
the second semiconductor multilayer structure is provided with
a fifth semiconductor layer of the first conductive type,
a sixth semiconductor layer of the second conductive type,
a seventh semiconductor layer of the first conductive type, and
an eighth semiconductor layer of the second conductive type wherein the fifth to eighth semiconductor layers are stacked sequentially in this order on the base material,
a first distance is smaller than a second distance wherein
the first distance is defined between a first face, which includes an end face of the second semiconductor layer on one side close to the base material end part, and a second face, which includes an end face of the fourth semiconductor layer on one side close to the base material end part, and
the second distance is defined between a third face, which includes an end face of the second semiconductor layer on one side far from the base material end part, and a fourth face, which includes an end face of the fourth semiconductor layer on one side far from the base material end part,
a third distance is equal to a fourth distance wherein
the third distance is defined between a fifth face, which includes an end face of the sixth semiconductor layer on one side in the first direction, and a sixth face, which includes an end face of the eighth semiconductor layer on the one side,
the fourth distance is defined between a seventh face, which includes an end face of the sixth semiconductor layer on the other side opposite to the one side, and an eighth face, which includes an end face of the eighth semiconductor layer on the other side, and
the second distance is equal to the third distance.

8. The semiconductor according to claim 6, wherein
the first conductive type is the N type, and
the second conductive type is the P type.

9. The semiconductor according to claim 7, wherein
the first conductive type is the N type, and
the second conductive type is the P type.

10. The semiconductor according to claim 6, wherein
the first conductive type is the P type, and
the second conductive type is the N type.

11. The semiconductor according to claim 7, wherein
the first conductive type is the P type, and
the second conductive type is the N type.

12. The semiconductor device according to claim 1, wherein
the first light emitting element and the second light emitting element are light emitting diodes.

13. The semiconductor device according to claim 1, wherein
the first organic insulating film and the second organic insulating film are formed of polyimide.

14. The semiconductor device according to claim 1, wherein
the base material is in a rectangle shape in a top view, having a longer side extending in a longitudinal direction and a shorter side extending in a lateral direction perpendicular to the longitudinal direction, and
the first direction is the longitudinal direction of the base material.

15. The semiconductor device according to claim 1, wherein
the first light emitting element is in a planar shape, and the second light emitting element is in a planer shape,
the planner shape of the first light emitting element is identical to the planar shape of the second light emitting element.

16. An optical print head, comprising:
a substrate, and
a semiconductor device array, wherein
a plurality of the semiconductor devices according to claim 1 is aligned on the substrate.

17. An image forming apparatus, comprising:
the optical print head according to claim 14.
